(19) United States
(12) Patent Application Publication
(10) Pub. No.: US 2014/0210555 A1
(43) Pub. Date: Jul. 31, 2014

(54) RADIO FREQUENCY SIGNAL AMPLIFIER AND AMPLIFYING SYSTEM

(71) Applicant: MICROELECTRONICS TECHNOLOGY, INC., Hsinchu (TW)

(72) Inventor: MING CHE LIOU, HSINCHU (TW)

(73) Assignee: MICROELECTRONICS TECHNOLOGY, INC., Hsinchu (TW)

(21) Appl. No.: 13/973,727

(22) Filed: Aug. 22, 2013

Related U.S. Application Data
(60) Provisional application No. 61/759,008, filed on Jan. 31, 2013.

(51) Int. Cl. H03F 3/193

(52) U.S. Cl. CPC H03F 3/193
USPC 330/296

(57) ABSTRACT

The present disclosure provides a radio frequency signal amplifier and amplifying system using coaxial cables to apply bias voltages to the control terminals of the transistors. The radio frequency signal amplifier includes a transistor connected between an input terminal and an output terminal, a first coaxial cable configured to couple a bias voltage to a control terminal of the transistor, a feed line connected between the bias voltage and the first coaxial cable, and a second coaxial cable connected between an open stub and the control terminal of the transistor.

### TECHNICAL FIELD

The present disclosure relates to a radio frequency (RF) signal amplifier, and more particularly, to a radio frequency signal amplifier and amplifying system using coaxial cables to apply gate bias voltages to the control terminals of the FET transistors.

### DISCUSSION OF THE BACKGROUND

Wireless communication systems, such as 3G or 4G long-term evolution (LTE) communication systems, present a challenge in designing high saturated power, high efficiency, and high linearity RF power amplifiers with wide modulation bandwidth signals. Generally, a “wideband” system is developed to satisfy the higher data rate requirements of advanced and modern communication systems. The wideband technology is highly focused on the signal modulation bandwidth in data, or base-band domains. In the RF application of the components and device, the device matching influences the operational video bandwidth (VBW) of the circuit and design patterns.

Conventionally, some combined passive components module can achieve 5% to 12% VBW for an instantaneous wideband signal on its carrier frequency Fc, such as the passive filter, RLC network, or matched circuitry pattern on its operating frequency. In contrast, for active components, such as high power transistors, achieving higher than 5% VBW is a difficult requirement and needs some special trade-off designs to attain the linearity of a 5% VBW range. For the high power amplifier transistor, the operating VBW can be defined as the transistor's linear operating bandwidth. The linear operating bandwidth range consists of two-tone inter-modulation distortion (IMD) re-growth levels and phase/delay/amplitude changes in a linear response with a low memory effect for different power levels and bandwidths. Having consistent IMD re-growth levels is very important for the digital pre-distortion (DPD) applications of new generation wireless power amplifiers. The appropriate DPD correction response requires a radio-frequency (RF) amplifier operated with low memory effects and lower non-linearity regrowth with 3 times of the operation VBW in a 3 dB level of the IMD re-growth changes at constant power.

For a 20 MHz LTE waveform, the RF power amplifier needs to have a bandwidth wider than 60 MHz VBW for the entire band coverage. Generally, the field effect transistor (FET) power amplifier modeling and characterization can attain a 70 MHz to 100 MHz modulation bandwidth for 1.9 GHz personal communication service (PCS) bands to 2.1 GHz universal mobile telecommunication system (UMTS) band transistors (3.6% to 5% of Fc). In an actual power amplifier module, the Q factor, transistor package, matching errors, and assembly differences should all be taken into consideration for its VBW. The module requires highly advanced designs by skilled persons in order to attain a wider VBW for any mass manufacturing amplifiers.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY

One aspect of the present disclosure provides a radio frequency signal amplifier and amplifying system using coaxial cables to bias the control gate terminal of the FET transistor.

A radio frequency signal amplifier according to this aspect of the present disclosure comprises a transistor connected between an input terminal (gate terminal) and an output terminal (drain terminal), a first coaxial cable configured to couple a bias voltage to a gate control terminal of the transistor, a feed line connected between the gate bias voltage and the first coaxial cable, and a second coaxial cable connected between an open stub and the gate control terminal of the transistor.

A radio frequency signal amplifying system according to another aspect of the present disclosure comprises a first transistor and a second transistor connected in parallel between an input terminal and an output terminal; a first coaxial cable configured to couple a first bias voltage to a first control terminal of the first transistor; a second coaxial cable configured to couple a second bias voltage to a second control terminal of the second transistor; a third coaxial cable connected between a first open stub and the first control terminal of the first transistor; and a fourth coaxial cable connected between a second open stub and the second control terminal of the second transistor.

The foregoing has outlined rather broadly the features and technical advantages of the present disclosure in order that the detailed description of the disclosure that follows may be better understood. Additional features and advantages of the disclosure will be described hereinafter, which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a schematic view of a single gate bias voltage supply design;

FIG. 2 shows an RF lineup block diagram to amplify the RF signals;

FIG. 3 is a schematic view illustrating a radio frequency signal amplifier according to one embodiment of the present disclosure;

FIG. 4 is a corresponding circuit diagram of the radio frequency signal amplifier in FIG. 3;

FIG. 5 is a schematic view illustrating a radio frequency signal amplifier according to another embodiment of the present disclosure;

FIG. 6 is a corresponding circuit diagram of the radio frequency signal amplifier in FIG. 5;

FIG. 7 is a schematic view illustrating a radio frequency signal amplifying system according to one embodiment of the present disclosure;

FIGS. 8 to 10 are VBW measurements on a gate matching with different configurations of a gate bias supply to the same LDMOS FET amplifier;

FIG. 11 is a measurement of the lower side IMD3 by CW two-tone testing;

FIG. 12 is a measurement of the upper side IMD3 by CW two-tone testing;

FIGS. 13 to 15 are WCDMA ACLR measurements on the symmetric IMD, and monotonic performance by the radio frequency signal amplifier shown in FIG. 3; and

FIGS. 16 to 18 are WCDMA ACLR measurements on the symmetric IMD, and monotonic performance by the radio frequency signal amplifier shown in FIG. 5.

### DETAILED DESCRIPTION

The following description of the disclosure accompanies drawings, which are incorporated in and constitute a part of this specification, and illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

The present disclosure is directed to a radio frequency signal amplifier and amplifying system using coaxial cables to apply gate bias voltages to the control terminals of the transistors. In order to make the present disclosure completely comprehensible, detailed steps and structures are provided in the following description. Obviously, implementation of the present disclosure does not limit special details known by persons skilled in the art. In addition, known structures and steps are not described in detail, so as not to limit the present disclosure unnecessarily. Preferred embodiments of the present disclosure will be described below in detail. However, in addition to the detailed to description, the present disclosure may also be widely implemented in other embodiments. The scope of the present disclosure is not limited to the detailed description, and is defined by the claims.

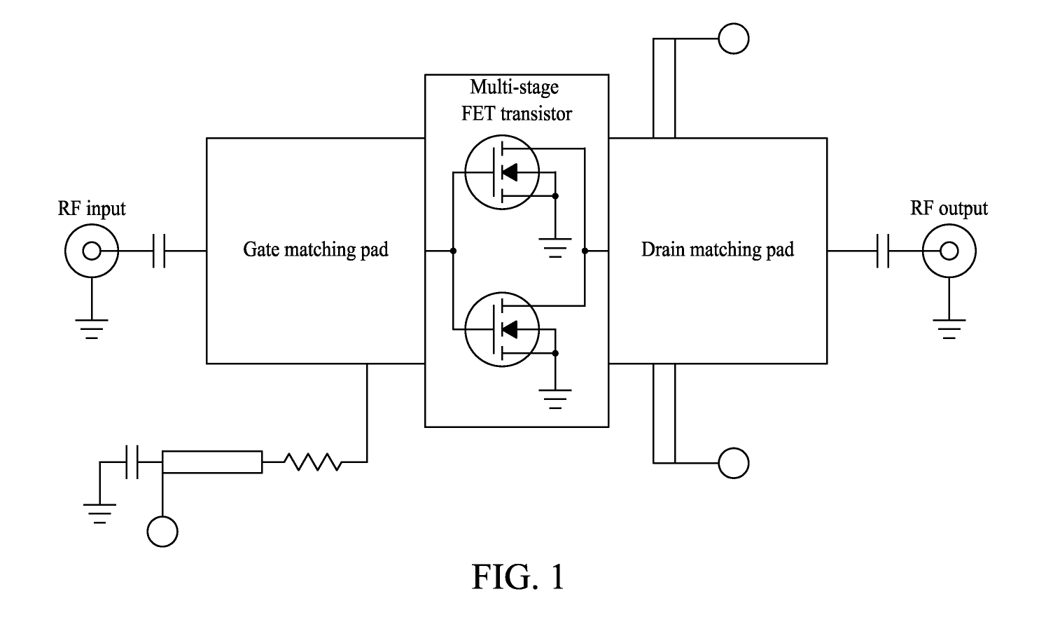

The new generation RF power amplifiers that support wide bandwidth or multi-carriers (MCPA) require higher saturated power transistors to increase RF power. To provide high RF power for 2.1 GHz applications, the LDMOS FET devices combine more transistor arrays or dies, resulting in a very wide lateral dimension. For example, a P_{1 dB} (1 dB compression point) to 320 W device has 30 mm on its lateral dimension, which internally combines 2 to 4 dies. The distance between the FET die at the peripheral of the LDMOS FET device and the power source is different from that between the FET die at the center of the LDMOS FET device. Such difference in distance causes a time response offset and delay to the FET dies, which limits the modulation bandwidth for the single gate bias voltage supply on the single side of the gate matching pattern, as shown in FIG. 1. The wide lateral dimension results in a non-synchronized operation on FET dies at a high frequency when wide modulation rate signals input to the LDMOS FET device.

Another effect that occurs due to the wide lateral dimension when combining arrays or dies is the development of very low impedance on the gate. The real part of impedance will be less than 5 Ohms for the trigger frequency on the transistor gate. Some LDMOS FETs combine 2 or 3 dies to generate more power; however, the gate input response impedance will be less than 3 Ohms on real part of impedance. To be precise, the LDMOS FET needs to use a resistor with very low resistance on the gate bias supply so as to attain a wider VBW with a flat IMD response and gain. In addition, the difference between the right and left arrays of the copper matching pad will cause an increased resistance for each array. However, the VBW of the amplifier will degrade if different gate bias voltages are applied to different FET arrays.

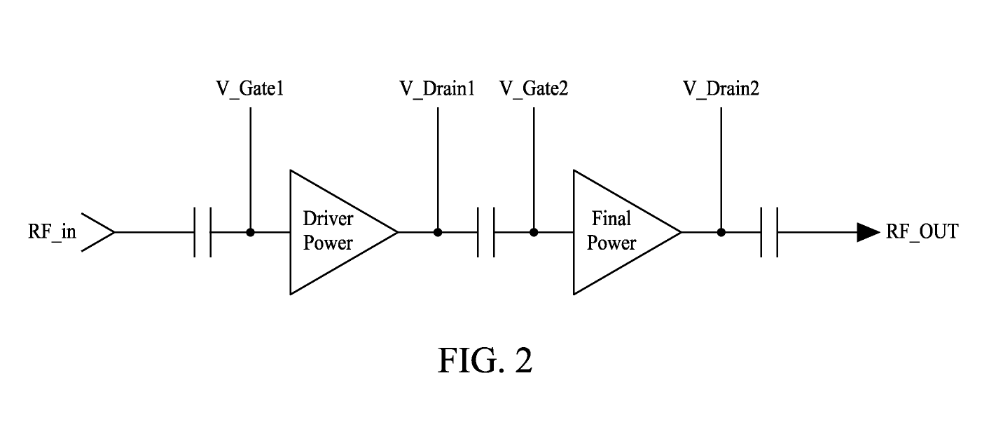

FIG. 2 shows an RF lineup block diagram to amplify the RF signals. For an amplifier module's RF line-up, the RF power is amplified by a front, or driver stage, to drive up more power to the final stage for high power outputs. Each amplifier stage's FET transistors use a drain voltage supply to supply the current source for the FET, and a gate voltage to control its FET operation conditions with a converted phase and amplify amplitude. Each stage can be used for the balance combined class AB, Doherty designs, or more transistors to combine for outputting more power. On a 3G or 4G waveform characteristic and 3G or 4G standard requirements, the wireless cellular base station will drive up between 20 W and 25 W antenna radiated power for each carrier with 6 to 8 dB PAR (Peak-to-Average Power ratio) CFR (Crest factor reduction) waveforms, or higher PAR by non-CFR waveforms. For a single carrier, including the duplexer and cable loss, the amplifier approximately outputs to higher than 45 Bm power. Considering the waveform PAR and back-off power that achieve better linearity and margins, the single carrier power amplifier (SCPA) needs to have at least 53 dBm saturated power. For an MCPA with three carriers or more, many MCPA designs need to have the capability to handle very high saturated power for up to more than 58 dBm or higher in order to attain appropriate margins for DPD gain expansion and efficient linearity. The challenge for FET transistor manufactures is to produce large scale transistors in one package and efficiently increase the power density to decrease as much thermal resistance as possible. In addition, the LDMOS, or GaN device can achieve 300 W to 400 W RF peak power performance in one package for a 700 MHz to 2.1 GHz band and a 600 W device on a VHF band. Such device internally includes several die arrays and creates a wide lateral dimension.

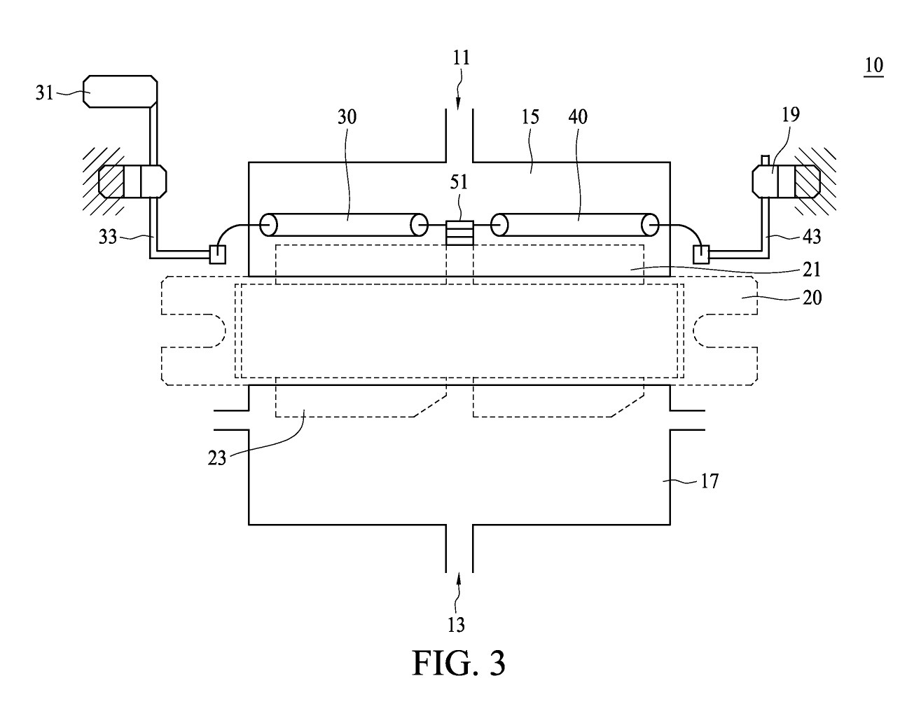

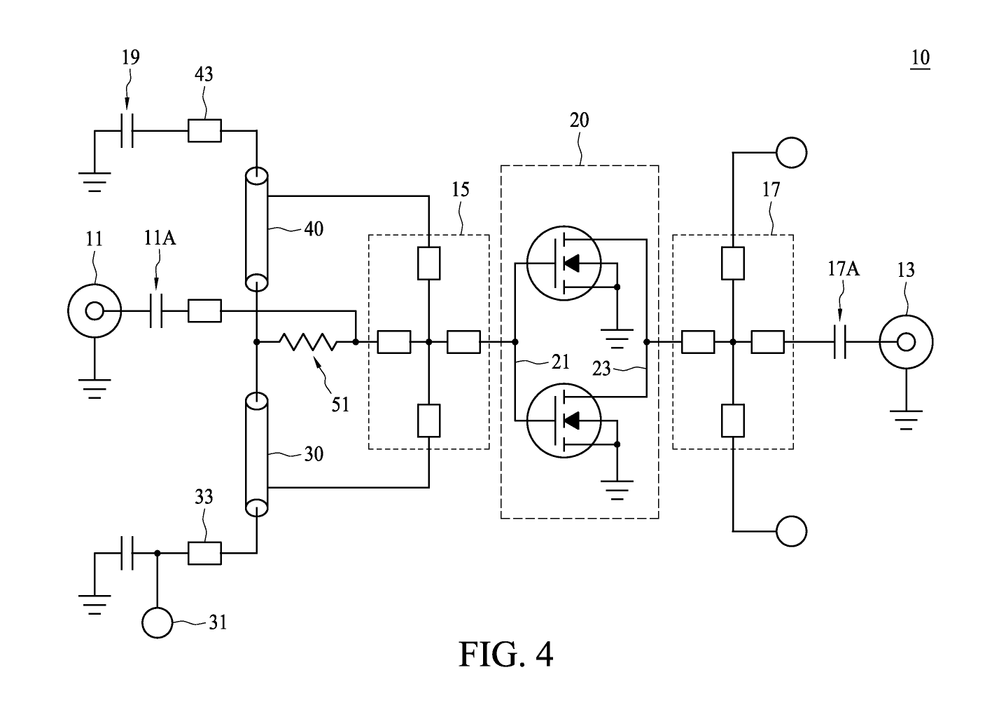

FIG. 3 is a schematic view illustrating a radio frequency signal amplifier 10 according to one embodiment of the present disclosure, and FIG. 4 is a corresponding circuit diagram of the radio frequency signal amplifier 10. In one embodiment of the present disclosure, the radio frequency signal amplifier 10 comprises a transistor 20 connected between an input terminal 11 and an output terminal 13; a first coaxial cable 30 configured to couple a bias voltage 31 to a control terminal 21 of the transistor 20; a feed line 33, such as a quarter wavelength feed line, connected between the bias voltage 31 and the first coaxial cable 30; and a second coaxial cable 40 connected between an open stub 43, such as a quarter wavelength stub, and the control terminal 21 of the transistor 20.

In one embodiment of the present disclosure, the transistor 20 is a field effect transistor having the control terminal (gate terminal) 21 and a conduction terminal (drain terminal) 23; the input terminal 11 is connected to the gate 21 of the transistor 20 via the control matching pad 15 and an input coupling capacitor 11A, and the output terminal 13 is connected to the drain 23 of the transistor 20 via a conduction matching pad 17 and an output coupling capacitor 17A. In an exemplary embodiment of the present disclosure, the transistor is an MRF8S19260H, supplied by Freescale Semiconductor, Inc.

In one embodiment of the present disclosure, the radio frequency signal amplifier 10 further comprises a first bias resistor 51 with one terminal connected to the first coaxial cable 30 and the second coaxial cable 40. In an exemplary embodiment of the present disclosure, the radio frequency signal amplifier 10 comprises a control matching pad 15 connected to the control terminal 21 of the transistor 20, and the first bias resistor 51 connects the first coaxial cable 30 and the second coaxial cable 40 substantially to a middle site of the control matching pad 15 so as to apply the bias voltage 31 to the control terminal 21 of the transistor 20 via the control matching pad 15. In one embodiment of the present disclosure, the first coaxial cable 30 and the second coaxial cable 40 are arranged in a symmetrical manner with respect to the middle site of the control matching pad 15.

In an exemplary embodiment, the first coaxial cable 30 and the second coaxial cable 40 are connected to the control matching pad 15 in a symmetrical manner; the core conductors of the first coaxial cable 30 and the second coaxial cable 40 are used to conduct the bias voltage 31; and the shielding conductors of the first coaxial cable 30 and the second coaxial cable 40 are bonded to the control matching pad 15 by soldering.

From the RF input terminal 11 to the power transistor 20, the input coupling capacitor 11A is used to couple the RF signal and block the DC portion of the gate 21 of the power transistor 20. The gate matching pad 15 and some Hi-Q designed capacitors convert the input impedance from the coupling capacitor 11A to the input impedance of the gate 21 of the power transistor 20 in order to smoothly lower the VSWR to feed the RF signal to the power transistor 20. In addition, the gate 21 of the power transistor 20 needs to apply a stand voltage to bias the gate 21 at a higher voltage than the threshold voltage.

Generally, the lateral N-channel power MOSFET requires a positive gate voltage applied to the FET's gate metal so as to create the oxide-silicon (inversion layer) interface's electron mobility. The application of the gate voltage is not an issue for the single FET chip transistor, but it will be an issue when there are many FET chip arrays that are combined together, such as a large scale LDMOSFET. In view of the above, to keep all FET arrays at the same bias voltage at the same time with high trigged frequency, it is not suitable to use the single gate bias voltage supply design, as shown in FIG. 2.

Referring to FIG. 3 and FIG. 4, the bias voltage 31 is applied to the center point of the FET's gate lead (the control terminal 21 of the power transistor 20). To spread the bias voltage 21 from the center point of the gate lead so as to keep the same voltage being applied to all the internal FET arrays, the bias voltage is applied via the biasing resistor 51 with the coaxial cable 30; for example, a 0.034″ 50 Ohm semi-rigid coaxial cable. The central conductive wire of the coaxial cable 40 is connected to the symmetric dummy gate supply with the quarter wavelength open stub 43 by using a blocking capacitor 19.

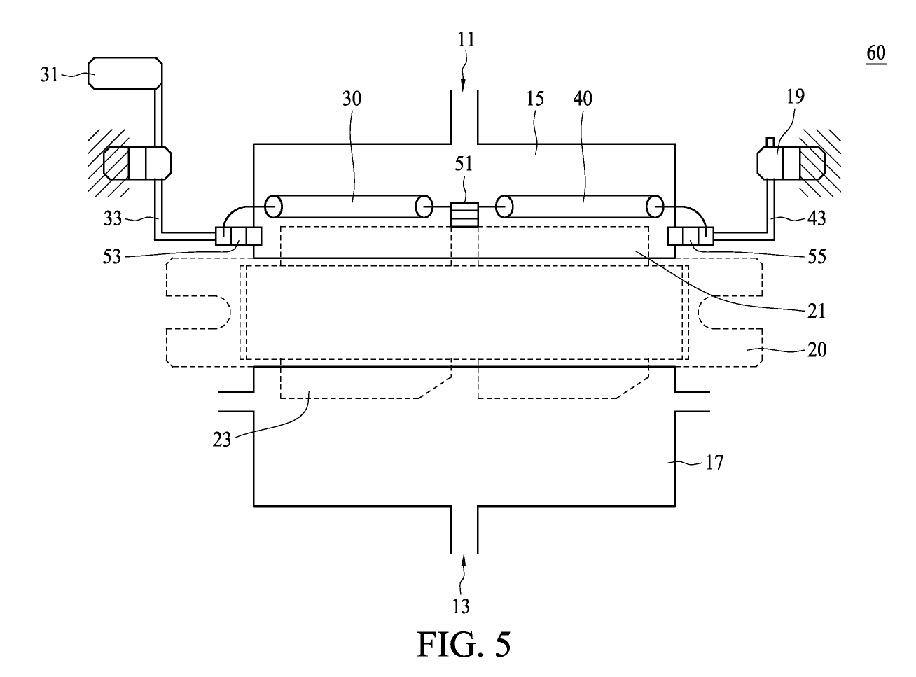

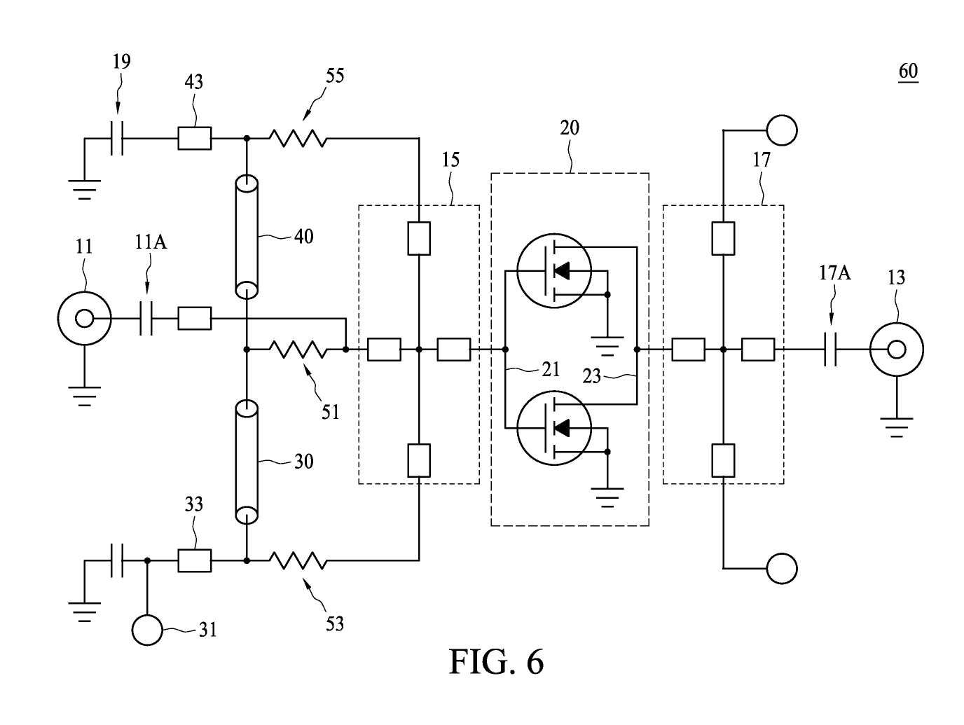

FIG. 5 is a schematic view illustrating a radio frequency signal amplifier 60 according to another embodiment of the present disclosure, and FIG. 6 is a corresponding circuit diagram of the radio frequency signal amplifier 60. In one embodiment of the present disclosure, compared to the radio frequency signal amplifier 10 shown in FIG. 3, the radio frequency signal amplifier 60 in FIG. 5 further comprises a second bias resistor 53 connected between the feed line 33 and the control matching pad 15, and a third bias resistor 55 connected between the open stub 43 and the control matching pad 15.

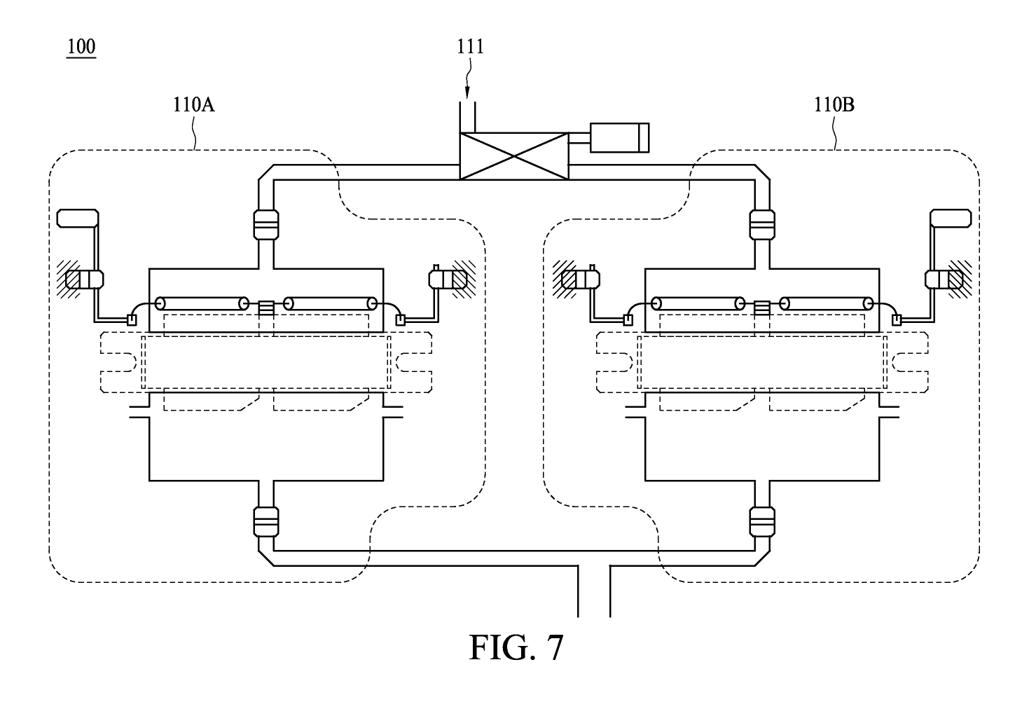

FIG. 7 is a schematic view illustrating a radio frequency signal amplifying system 100 according to one embodiment of the present disclosure. In one embodiment of the present disclosure, the radio frequency signal amplifying system 100 comprises a carrier signal amplifier 110A and a peak signal amplifier 110B connected in parallel between an input terminal 111 and an output terminal 113. In an exemplary embodiment of the present disclosure, the carrier signal amplifier 110A may be implemented substantially by the radio frequency signal amplifier 10 shown in FIG. 3 or FIG. 5 and biased at a first voltage, and the peak signal amplifier 110B can also be implemented substantially by the radio frequency signal amplifier 10 shown in FIG. 3 or FIG. 5, but biased at a second voltage different from the first voltage.

The radio frequency signal amplifying system 100 utilizes the Doherty amplifying technique, which is a popular RF power amplifier design configuration for 3G and 4G applications since it increases the amplifier efficiency by providing enough peak power capability to support the high peak power signals. The load modulation amplifier's operating frequency bandwidth constrains on the Doherty power combiner by the quarter wavelength transformer matching pattern, which also limits its VBW as well. The Doherty transformer type can attain 5% or higher VBW, but still has a lower VBW than class AB balanced combined amplifiers. To maintain the Doherty power amplifier with a higher VBW, the design on the gate bias and drain supply become very critical factors and would greatly impact the signal modulation bandwidth, especially on the gate bias feed-in designs. The class A or class AB carrier amplifiers require a wide modulation bandwidth with high efficiency in order to amplify the low crest factor power portion to mostly 60% of the total Doherty power output. In addition, 40% of the high crest factor power portion, or extended gain expansion by DPD, will be loaded by the peaking amplifiers. In contrast, class C peaking amplifiers operate in pulse type amplifiers with a high pulsed power output. The amplifier requires more flat gain flatness and more VBW to support appropriate margins for DPD gain expansion on the wide bandwidth, and comfortable IMD re-growth for DPD correction. On another amplifier modeling view, the narrow and wideband, modulated signals on the amplifier designs need consistent AM-AM and AM-PM response characteristics.

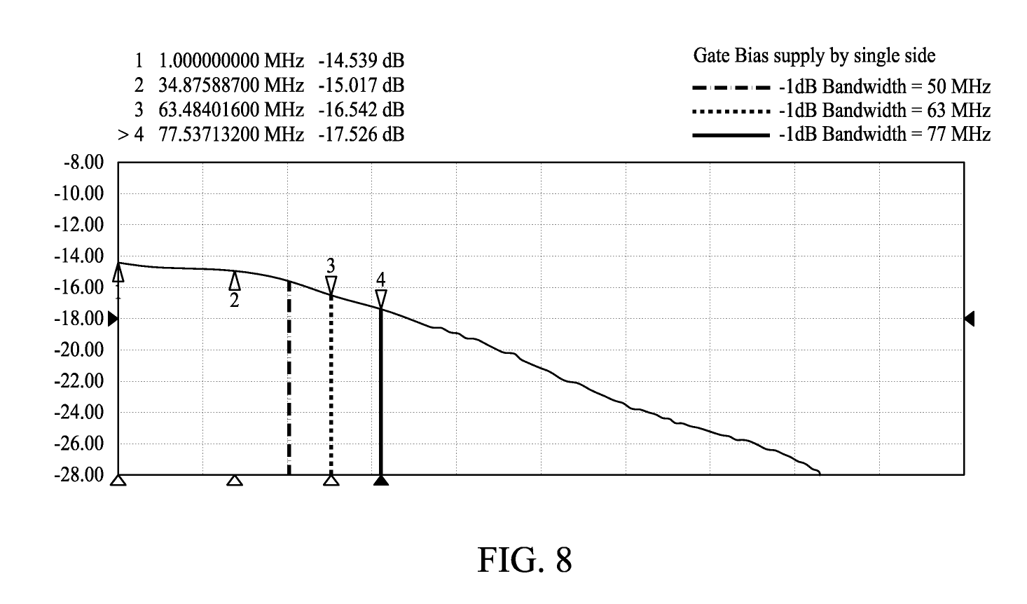

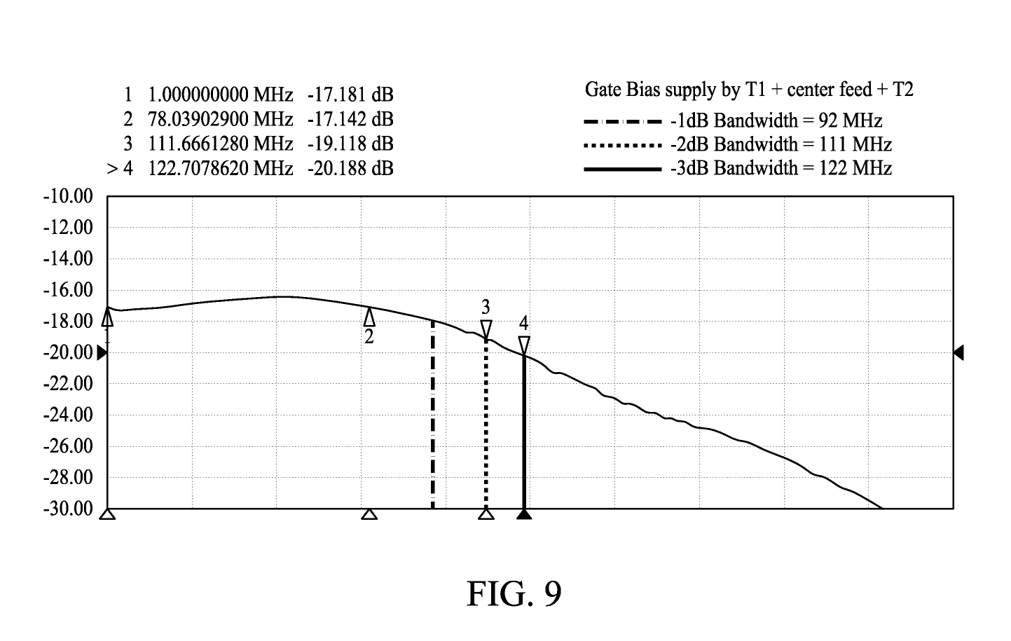

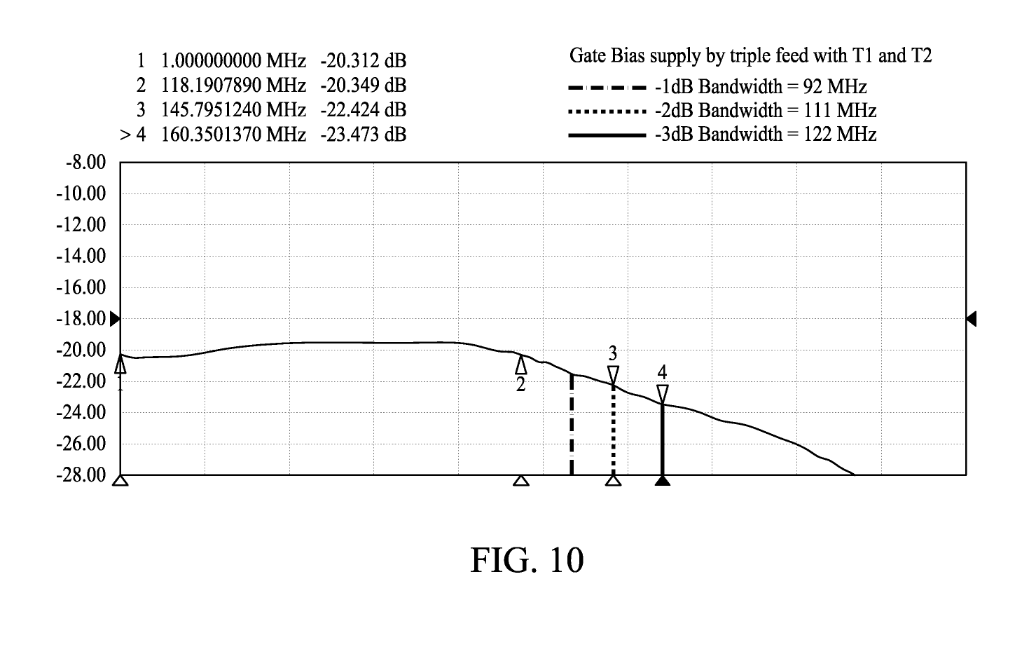

FIGS. 8 to 10 are VBW measurements on a gate matching with different configurations of a gate bias supply to the same LDMOS FET amplifier. FIG. 8 shows a VBW measurement of a single gate supply technique without a symmetric open stub, having 1 dB VBW at 50M, 2 dB VBW at 63 MHz, and 3 dB VBW at 77 MHz. FIG. 9 is a VBW measurement of the radio frequency signal amplifier 10 shown in FIG. 3, having 1 dB VBW at 92 MHz, 2 dB VBW at 111 MHz, and 3 dB VBW at 122 MHz, which has a VBW extension that is about 2 times greater than that of the single gate supply technique. FIG. 10 is a VBW measurement of the radio frequency signal amplifier 60 shown in FIG. 5, having 1 dB VBW at 132 MHz, 2 dB VBW at 145 MHz, and 3 dB VBW at 160 MHz, which has a VBW extension that is about 2.3 times greater than that of the single gate supply technique.

The VBW sweep testing only shows the gate matching and gate biasing bandwidth. In the passive testing, the passive circuitry can gain more than 5% VBW for the design patterns. The testing results can be acquired by combining the transistor's active testing with the transistor's active responses. Generally, the transistor with matching pad testing utilizes the two-tone sweep to acquire the modeling and characterization of operating VBW. Also, the two-tone testing acquires the IMD3 and IMD5 results by using the amplifier network results in the IMD linear changes.

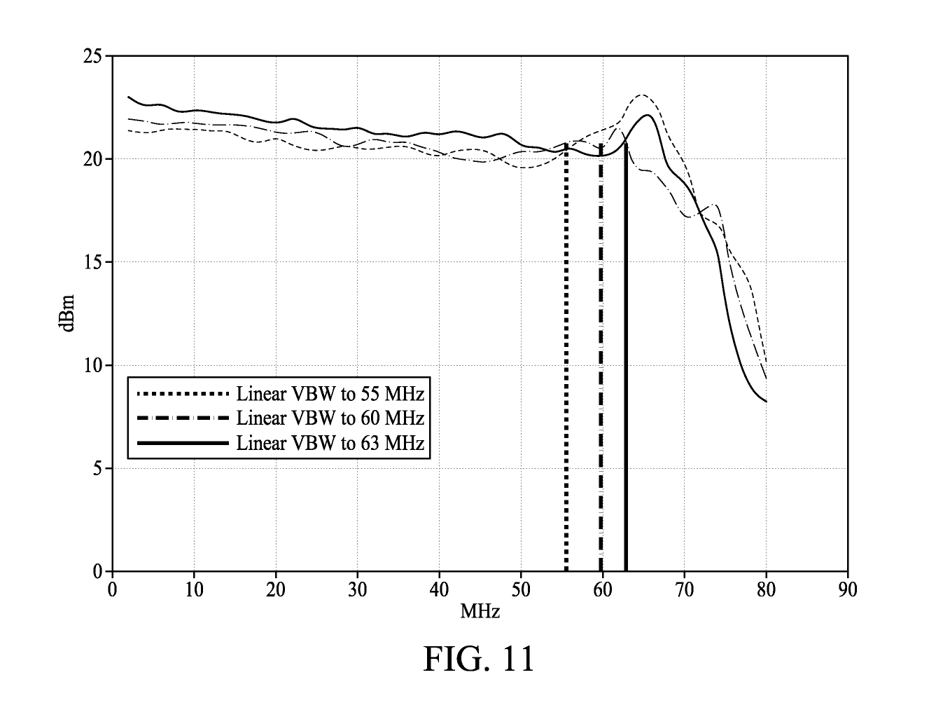

FIG. 11 is a measurement of the lower side IMD3 by CW (continuous wave) two-tone testing, wherein the frequencies are 1930 MHz and 1990 MHz, respectively. The power to the two-tones is 47 dBm, and the saturation power (Psat) of the LDMOS FET is 56.1 dBm. The single gate bias feed-in technique has a linear IMD3 bandwidth at 55 MHz; in contrast, the linear IMD3 bandwidth is increased up to 60 MHz with a center feed-in gate bias implemented by a coaxial with an open stub in the radio frequency signal amplifier 10 shown in FIG. 3, and up to 63 MHz with a triple feed-in technique in the radio frequency signal amplifier 60 shown in FIG. 5.

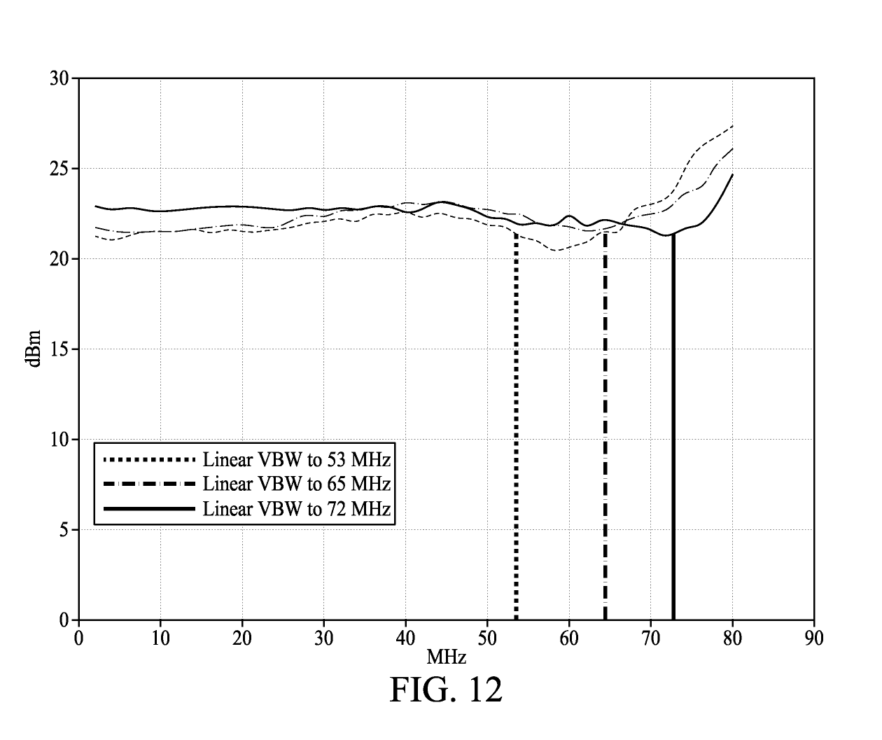

FIG. 12 is a measurement of the upper side IMD3 by CW two-tone testing, wherein the frequencies are 1930 MHz and 1990 MHz, respectively. The power to the two-tones is 47 dBm, and the saturation power (Psat) of the LDMOS FET is 56.1 dBm. The single gate bias feed-in technique has a linear IMD3 bandwidth at 53 MHz; in contrast, the linear IMD3 bandwidth is increased up to 65 MHz with a center feed-in gate bias implemented by a coaxial with an open stub in the radio frequency signal amplifier 10 shown in FIG. 3, and up to 72 MHz with a triple feed-in technique in the radio frequency signal amplifier 60 shown in FIG. 5.

Two-tone testing or gate matching swept VBW testing can show the modeling and basic characterization of the transistor with a matching pad response. In actual system applications, the injected multi-carrier WCDMA waveform can attain a realistic response for the new designs.

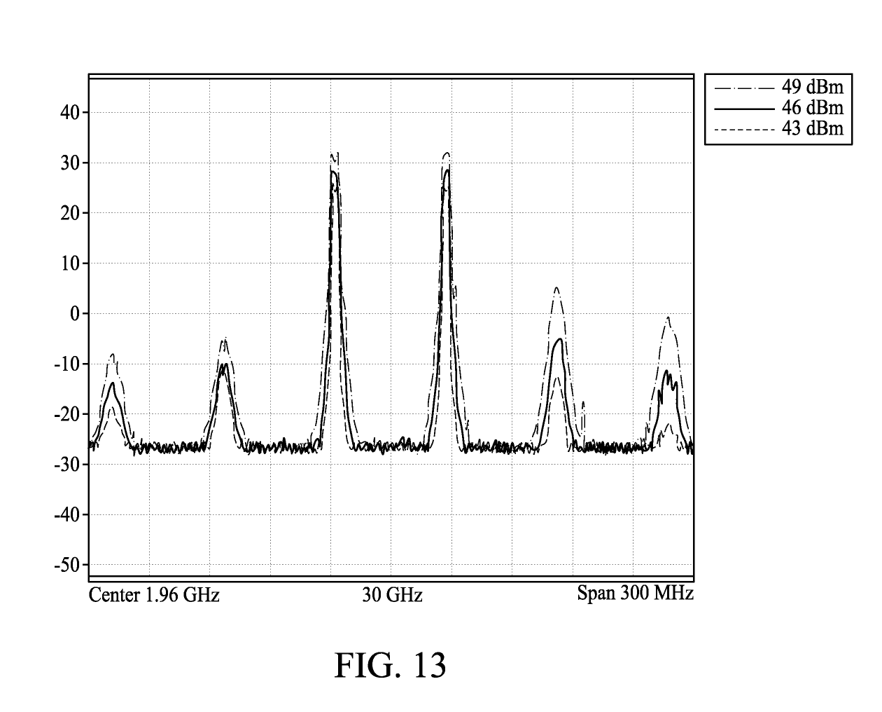

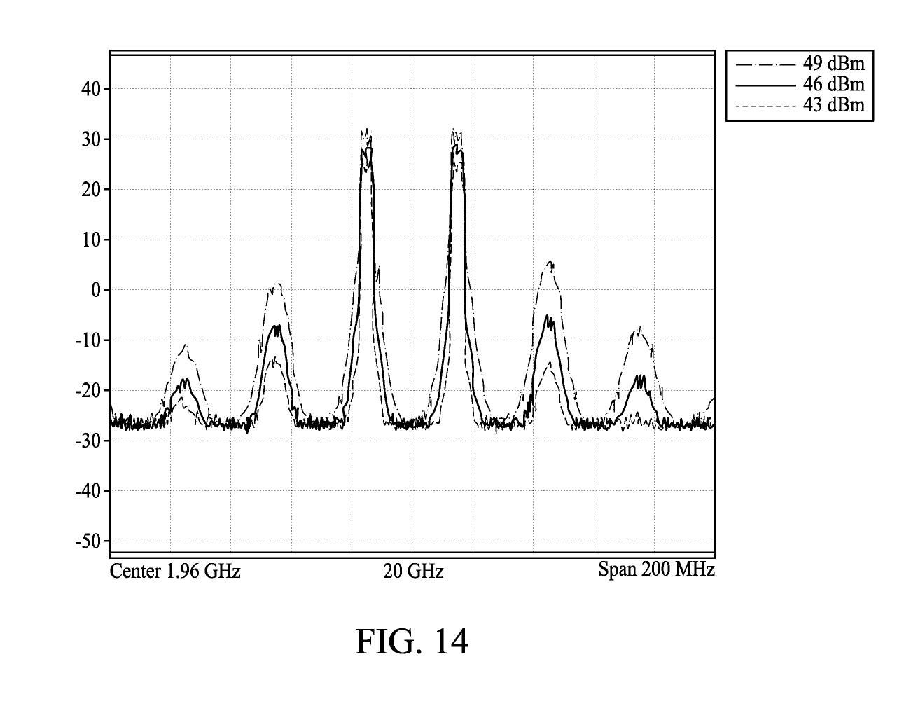

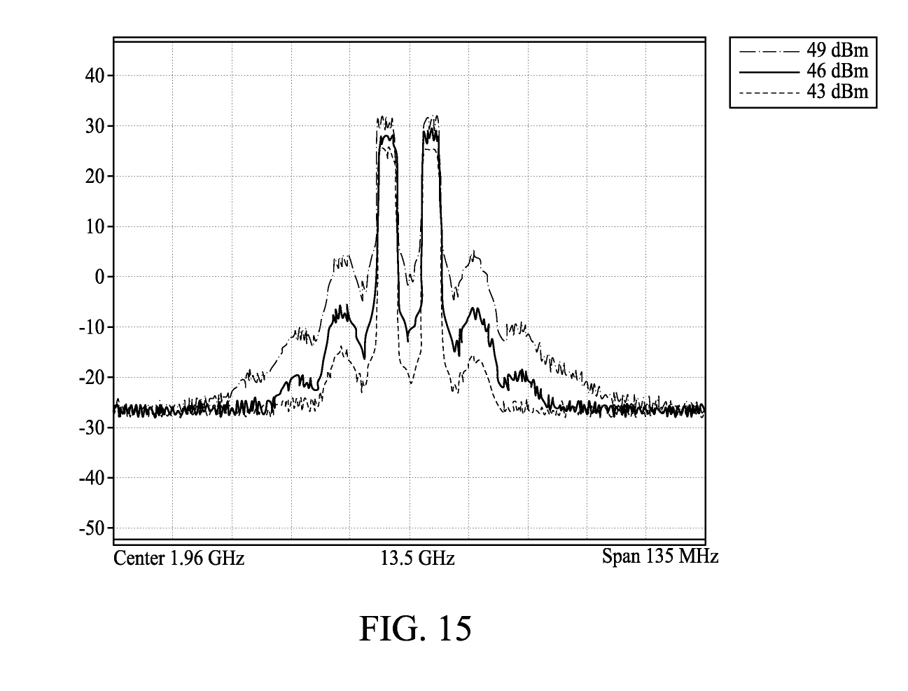

FIGS. 13 to 15 are WCDMA ACLR measurements on the symmetric IMD, and are performed by the radio frequency signal amplifier 10 shown in FIG. 3. The measurements show that the IMD with two WCDMA carriers has 55 MHz, 30 MHz and 10 MHz spacing with a center frequency at 1960 MHz, wherein the power of each carrier is 46 dBm with a PAR of 8.2 dB and the total power is 49 dBm. The upper side IMD3 is very consistent with different carrier frequency spacing and different carrier power levels. The lower side IMD3 drops down with higher carrier spacing under high power 49 dBm conditions. As shown in FIG. 11, the non-linearity on IMD3-L is tested by the high spacing and high power region on the CW two-tone IMD3 results. However, it remains consistent under 46 dBm conditions. The most critical aspect of 55 MHz carrier spacing is the limit of conventional PCS band application from 1930 MHz to 1990 MHz. The upper side IMD3 is very consistent with different carrier frequency spacing and different carrier power levels. The lower side IMD3 drops down with higher carrier spacing under high power 49 dBm conditions. As shown in FIG. 11, the non-linearity on IMD3-L is tested by the high spacing and high power region on the CW two-tone IMD3 results. However, it remains consistent under 46 dBm conditions. The IMD testing results also show the dynamic range with monotonic response on its IMD re-growth.

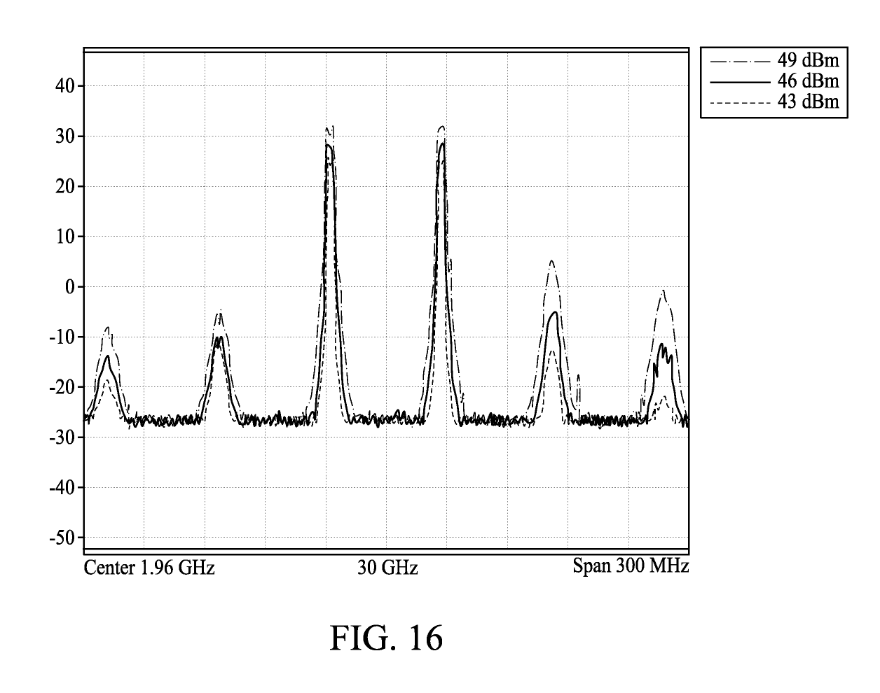

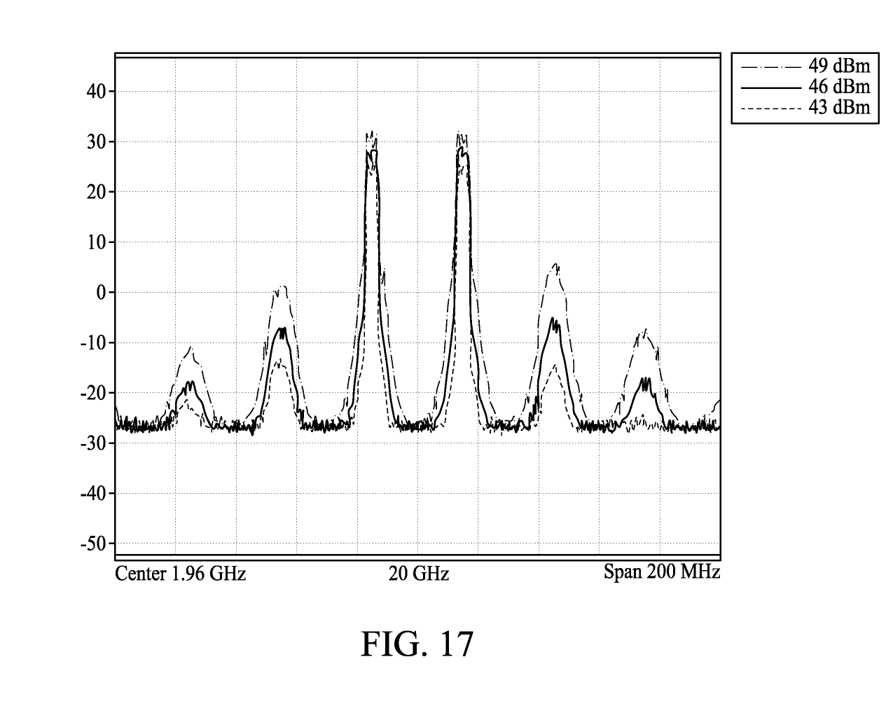

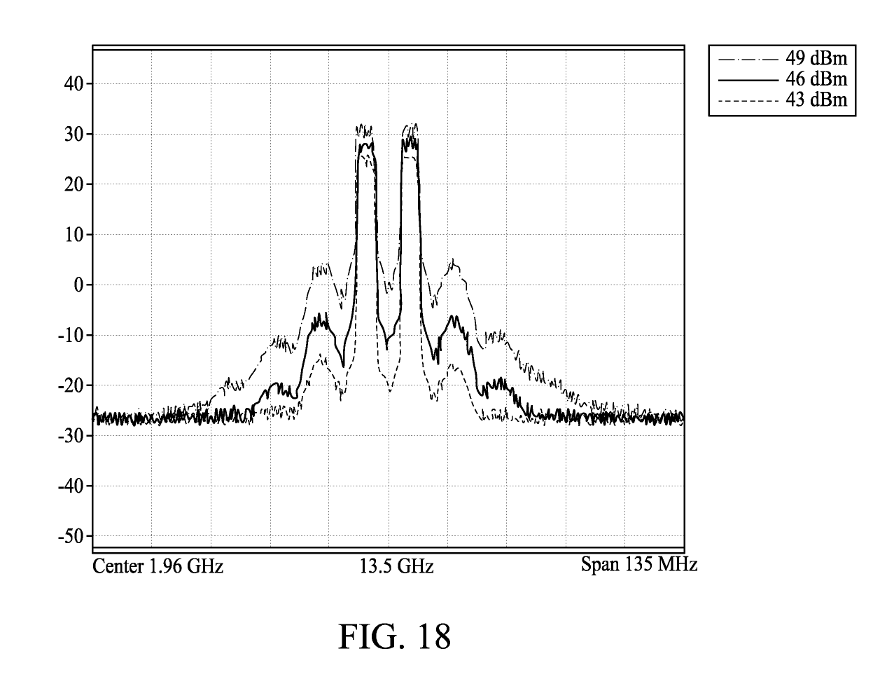

FIGS. 16 to 18 are WCDMA ACLR measurements on the symmetric IMD, and are performed by the radio frequency signal amplifier 60 shown in FIG. 5. The measurements show that the IMD with two WCDMA carriers has 55 MHz, 30 MHz and 10 MHz spacing. The upper side IMD3 is very consistent with different carrier frequency spacing and different carrier power levels. IMD5-U and IMD5-L are more consistent to 30 MHz than the testing results shown in FIGS. 13 to 15. Obviously, using the triple gate bias supply matching has extended the VBW. The lower side IMD3 drops down with higher carrier spacing under high power 49 dBm conditions. As shown in FIG. 11, the non-linearity on IMD3-L is tested by the high spacing and high power region on the CW two-tone IMD3 results, under 46 dBm conditions.

The embodiments of present disclosure use a simple mechanism with few modifications on the gate bias feed-in to the FET gate. However, the technique disclosed in the embodiments of the present application can extend the gate operating VBW up to 2.3 times more than that of the tradition designs, and reduces the non-linearity re-growth in IMD3 and IMD5 of the amplifier module. The gate voltage feed-in is implemented by using a miniature coaxial cable to prevent possible oscillation on the gate side. Using the symmetric open stub designs can reduce the chance of fundamental oscillation on the gate and provide a symmetric pattern to the transistor array for the VBW extension. The multi-point feed-in voltage to the FET's gate disclosed in the embodiments of the present application can keep all FET arrays at the same voltage level to bias the transistor in the same operating condition. In addition, the multi-point feed-in voltage to the FET's gate reduces the timing difference and un-synchronized supply characteristics for each array. The multiple feed-in technique can be used to provide a higher power density device with a wider lateral dimension LDMOS power FET device.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A radio frequency signal amplifier, comprising:
a transistor connected between an input terminal and an output terminal;
a first coaxial cable configured to couple a bias voltage to a control terminal of the transistor;
a feed line connected between the bias voltage and the first coaxial cable; and
a second coaxial cable connected between an open stub and the control terminal of the transistor.

2. The radio frequency signal amplifier of claim 1, further comprising a first bias resistor connected to the first coaxial cable and the second coaxial cable.

3. The radio frequency signal amplifier of claim 2, further comprising a control matching pad connected to the control terminal of the transistor, wherein the first bias resistor connects the first coaxial cable and the second coaxial cable substantially to a middle site of the control matching pad.

4. The radio frequency signal amplifier of claim 1, further comprising:
a control matching pad connected to the control terminal of the transistor;
a second bias resistor connected between the feed line and the control matching pad; and
a third bias resistor connected between the open stub and the control matching pad.

5. The radio frequency signal amplifier of claim 4, wherein the second bias resistor and the third bias resistor are connected to the control matching pad in a symmetrical manner.

6. The radio frequency signal amplifier of claim 4, wherein the first coaxial cable and the second coaxial cable are connected to the control matching pad in a symmetrical manner.

7. The radio frequency signal amplifier of claim 1, wherein the first coaxial cable and the second coaxial cable are arranged in a symmetrical manner with respect to a middle site of the control matching pad.

8. The radio frequency signal amplifier of claim 1, wherein the transistor is a field effect transistor having a gate and a drain, the input terminal is connected to the gate of the transistor, and the output terminal is connected to the drain of the transistor.

9. A radio frequency signal amplifying system, comprising:
a first transistor and a second transistor connected in parallel between an input terminal and an output terminal;
a first coaxial cable configured to couple a first bias voltage to a first control terminal of the first transistor;
a second coaxial cable configured to couple a second bias voltage to a second control terminal of the second transistor;
a third coaxial cable connected between a first open stub and the first control terminal of the first transistor; and
a fourth coaxial cable connected between a second open stub and the second control terminal of the second transistor.

10. The radio frequency signal amplifying system of claim 9, further comprising:
a first bias resistor connected to the first control terminal of the first transistor; and
a second bias resistor connected to the second control terminal of the second transistor.

11. The radio frequency signal amplifying system of claim 10, wherein the first bias resistor connects the first coaxial cable substantially to the first control terminal of the first transistor via a middle site of a first control matching pad, and the second bias resistor connects the second coaxial cable substantially to the control terminal of the second transistor via a middle site of a second control matching pad.

12. The radio frequency signal amplifying system of claim 9, further comprising:
a first feed line connected between the first bias voltage and the first coaxial cables; and
a second feed line connected between the second bias voltage and the second coaxial cable.

13. The radio frequency signal amplifying system of claim 12, further comprising:
a first control matching pad connected to the first control terminal of the first transistor; and
a second control matching pad connected to the second control terminal of the second transistor.

14. The radio frequency signal amplifier of claim 13, further comprising:
a first pair of bias resistors connecting the first feed line and the first open stub to the first control matching pad; and
a second pair of bias resistors connecting the second feed line and the second open stub to the second control matching pad.

15. The radio frequency signal amplifying system of claim 14, wherein the first pair of bias resistors are connected to the first control matching pad in a symmetrical manner.

16. The radio frequency signal amplifying system of claim 14, wherein the second pair of bias resistors are connected to the second control matching pad in a symmetrical manner.

17. The radio frequency signal amplifying system of claim 9, wherein the first coaxial cable and the third coaxial cable are arranged in a symmetrical manner with respect to a middle site of the first control matching pad.

18. The radio frequency signal amplifying system of claim 19, wherein the second coaxial cable and the fourth coaxial cable are arranged in a symmetrical manner with respect to a middle site of the second control matching pad.

19. The radio frequency signal amplifying system of claim 9, wherein the first transistor is a field effect transistor having a first gate and a first drain, the first gate is connected to the input terminal, and the first drain is connected to the output terminal.

20. The radio frequency signal amplifying system of claim 19, wherein the second transistor is a field effect transistor having a second gate and a second drain, the second gate is connected to the input terminal, and the second drain is connected to the output terminal.
